(19) United States
(12) Patent Application Publication
(10) Pub. No.: US 2002/0160616 A1
(43) Pub. Date: Oct. 31, 2002

(54) Integrated circuit trench etch with incremental oxygen flow

(76) Inventors: Thomas E. Grebs, Mountaintop, PA (US); Joseph L. Cumbo, West Wyoming, PA (US)

Correspondence Address: Thomas R. FitzGerald, Esq., Jaeckle Fleischmann & Mugel, LLP, 39 State Street, Rochester, NY, 14614-1310, US

(21) Appl. No.: 09/797,323

(22) Filed: Mar. 1, 2001

Related U.S. Application Data
(60) Provisional application No. 60/234,563, filed on Sep. 22, 2000.

(51) Int. Cl. H01L 21/302; H01L 21/461

(52) U.S. Cl. 438/704; 438/745

(57) ABSTRACT

Trenches are made in an integrated circuit by a process that incrementally increases the amount of oxygen during a trench etch. The trench may be an isolation trench or a gate trench for a QVDMOS device.

### CROSS-REFERENCE TO RELATED APPLICATIONS

This application claims the benefit of U.S. Provisional application Ser. No. 60/234,563, filed Sep. 22, 2000.

### BACKGROUND OF THE INVENTION

Cross-sectional SEMs of trench structures show that as the pitch of the device increases greater than 1. Sum, the sidewall profiles can change from favorable to non-favorable (re-entrant in shape), as shown in FIGS. 1 and 2. Such trench structures are found in integrated circuits and are used for isolation and for gates in quasi vertical DMOS (QVDOMS) integrated circuits. After the trench is formed, various films (poly and BPSG) are deposited and etched. The filled trenches exhibit void-free fills when the pitch is below 1.5 μm. As the pitch increases greater than 1.5 μm, the trench profile becomes re-entrant and thus keyholes and voids are formed in the subsequent films, thus effecting device yield, mainly Igss issues. FIG. 3 shows a BPSG film with voids that led to an Igss failure.

### DRAWINGS

FIG. 1 is shows prior art trenches with a pitch less than 1.5 microns.

FIG. 2 shows prior art trenches with a pitch greater than 1.5 microns.

FIG. 3 shows a prior art trench with a BPSG film and voids.

FIGS. 4 and 5 shows trenches etched with the invention's process and without re-entrant profiles or voids.

FIG. 6. is a top view of multiple trenches with no voids.

FIG. 7 is a schematic view of an integrated circuit having an isolation trench.

FIG. 8 is a schematic view of an integrated circuit with a QVDMOS formed with the trench process of the invention.

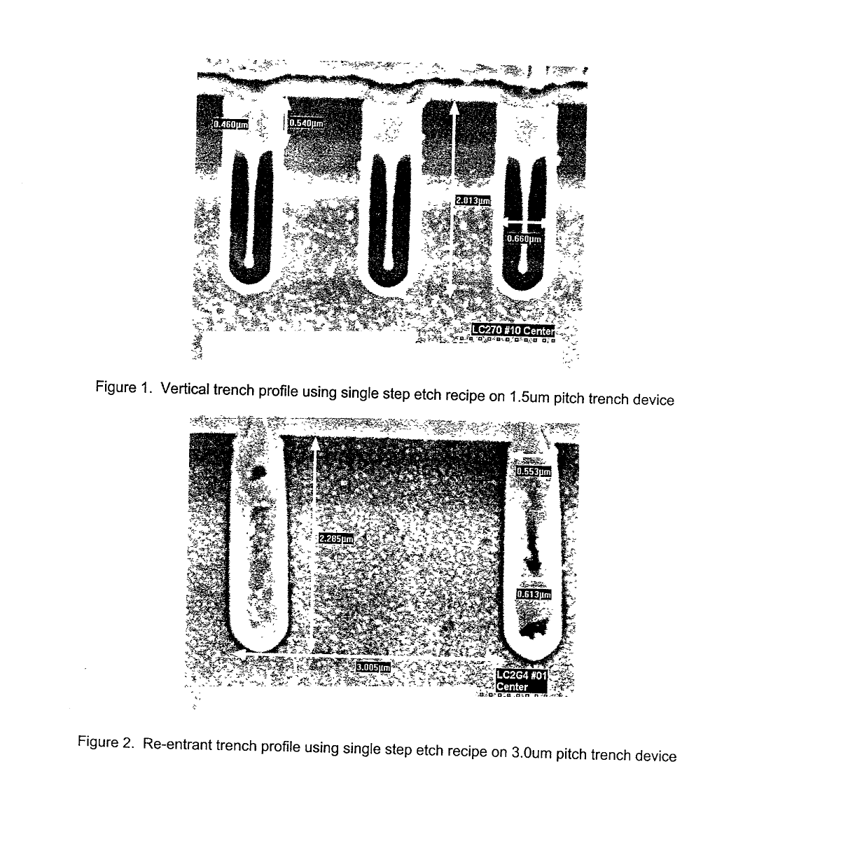

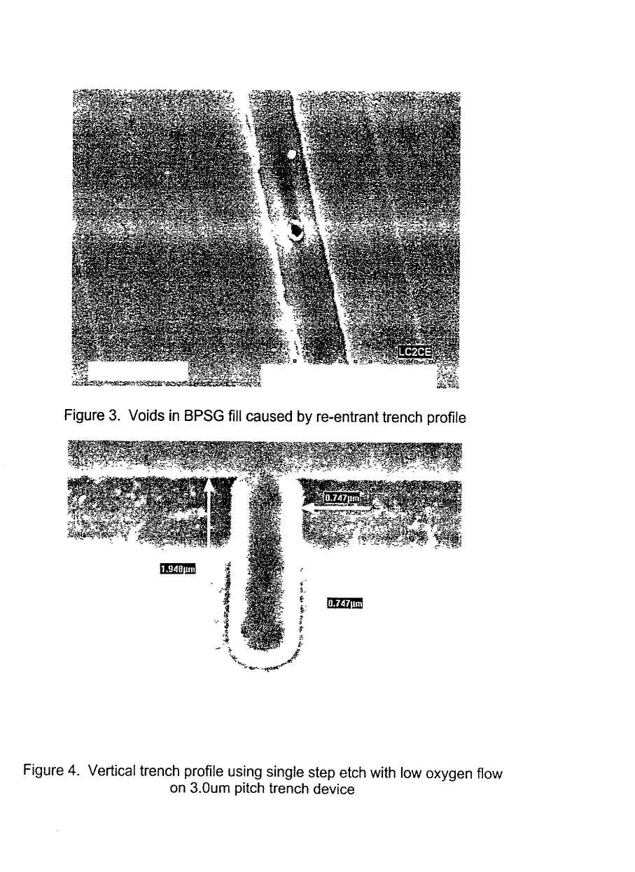

### DETAILED DESCRIPTION

In order to reduce the effects of the re-entrant profiles, it was found that the oxygen gas flow controls the amount of sidewall passivation generated to control the lateral etch of the silicon. A trench mask pattern is formed on the surface of semiconductor substrate having an integrated circuit. The circuit may be formed before, after, or during creation of the trench, depending upon the function (isolation or gate) of the trench. A trench mask pattern of an etch resistant layer is formed over the substrate with openings defining the trenches. For a plasma etch operation, a typical resist structure comprises a low temperature oxide. During plasma etching oxygen flow was decreased significantly (by 56%, from 34 to 15 sccm) and caused the silicon to have an etch bias of 0.25 μm from an LTO opening of 0.45 μm for wide pitch designs, as compared to 0.05 μm for narrow (1.5 μm) pitch designs. The oxygen ions tend to passivate the walls of the trench. However, fluorine ions from the SF6 gas etch silicon at a much faster rate than the oxygen ions could passivate the silicon sidewall, thus preventing lateral etching. One would think that this lateral etch could be prevented if a higher oxygen flow was used. However, it was observed that etching with high oxygen flow over-passivates the trench and produces unwanted negative artifacts, i.e., “grass” which causes rough surfaces. The surfaces of these trenches are used to form the gate oxide, but with very rough surfaces the gate oxide quality is degraded and leads to device failure.

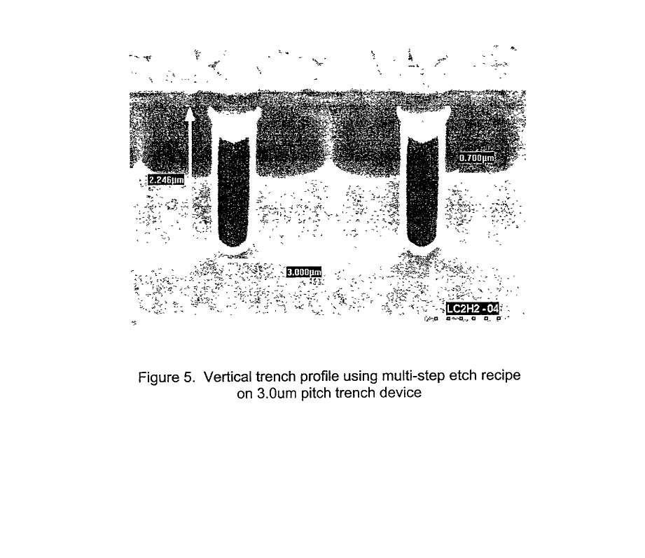

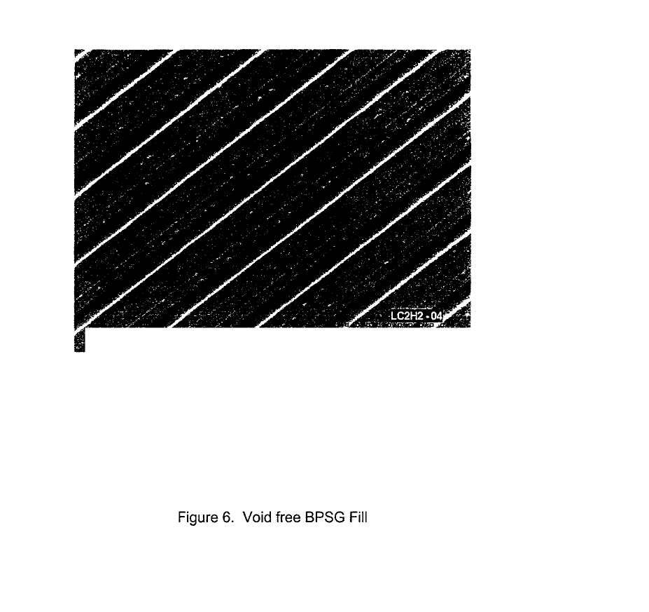

The new process breaks apart the main etch step of the trench etch into multiple segments. Each segment increases the oxygen flow by 5 sccm every step while maintaining the other etch parameters at their conventional respective settings. The amount of time required for each segment was equal but the intervals could be adjusted as one determines the need to add more sidewall passivation to prevent lateral etching of the silicon. This is sometimes referred to as “bowing” as shown in FIG. 2. Ramping the oxygen gas flow in discrete prevents grass formation from forming thus acceptable gate oxide quality with trench profiles and widths that are not re-entrant and over-sized, as shown in FIGS. 4 and 5. As shown in FIG. 5, the BPSG is now void-free, thereby reducing the risk of Igss failures. It is likely that the oxygen could be continuously increased and achieve similar results.

A typical etch recipe is shown in Table 1. That process and recipe causes re-entrant trench profiles when etching trenches that have pitches wider than 1.5 μm. The invention process provides a multi-step etch recipe that etches trenches where the trench pitch is greater than 1.5 μm. The process parameters are shown in Table 2. Oxygen gas flow rates and times can be adjusted to maintain a positive slope to the trench profiles to prevent any bowing from occurring.

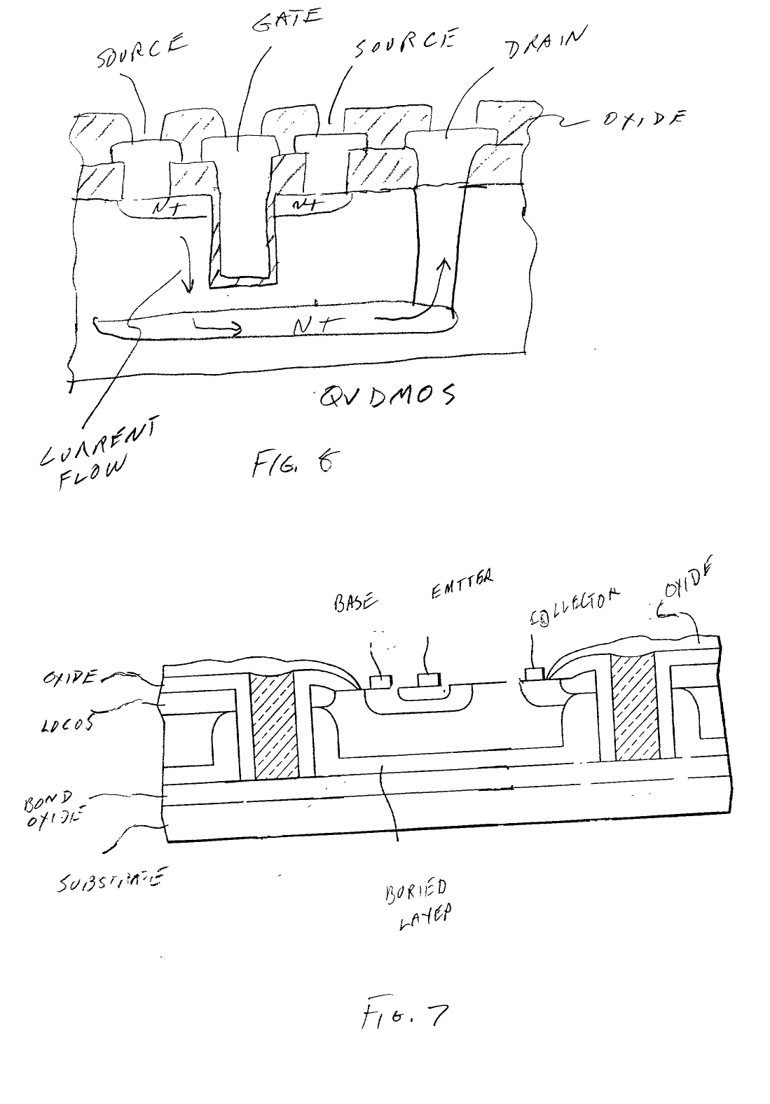

Although this innovation has been shown to work for N-channel Dense Trench technology, it could be applied to other semiconductor technologies and to various pitches and trench widths. The process and the resulting trenches are applicable to discrete devices and to integrated circuits. The trenches formed by the process may be isolation trenches or gate trenches. For example, a gate trench could be formed in a quasi-vertical DMOS device such as shown and described in U.S. Pat. No. 5,777,362, issued to Lawrence Pearce on Jul. 7, 1998, and assigned to the same assignee as this patent, and incorporated herein by reference. The individual QVDMOS devices may be isolated with trenches formed by the same process as the one used to form the gate trench. An isolation trench for an integrated circuit is shown in U.S. Pat. No. 5,920,108 and its disclosure is incorporated herein by reference. Examples of the isolation trenches the gate trenches in a QVDMOS integrated circuit are shown in FIGS. 7 and 8.

TABLE 1
Standard etch recipe used for 1.5 um pitch trench devices

| | Stable | BT | Stable | Ignition | Main Etch |
|---|---|---|---|---|---|
| Press (mT) | 10 | 10 | 80 | 80 | 80 |
| TCP Power (W) | 0 | 300 | 0 | 500 | 500 |
| Bias Power (W) | 0 | 100 | 0 | 25 | 25 |
| C12 (sccm) | 100 | 100 | 0 | 0 | 0 |
| 02 (sccm) | 0 | 0 | 34 | 34 | 34 |
| He (sccm) | 0 | 0 | 280 | 280 | 280 |
| SF6 (sccm) | 0 | 0 | 0 | 0 | 46 |
| Step Type | Stable | Time | Stable | Time | Time |
| Time (sec.) | 30 | 10 | 20 | 7 | 60 |

TABLE 2
Multi-step etch recipe used for >1.5 um pitch trench devices

| | Stable | BT | Stable | Ignition | Etch 1 | Etch 2 | Etch 3 | Etch 4 | Etch 5 | Etch 6 | Etch 7 | Etch 8 |
|---|---|---|---|---|---|---|---|---|---|---|---|---|
| Press (mT) | 10 | 10 | 60 | 60 | 60 | 60 | 60 | 60 | 60 | 60 | 60 | 60 |
| TCP Power | 0 | 300 | 0 | 500 | 500 | 500 | 500 | 500 | 500 | 500 | 500 | 500 |
| (W) | | | | | | | | | | | | |
| Bias Power | 0 | 10 | 0 | 25 | 25 | 25 | 25 | 25 | 25 | 25 | 25 | 25 |
| C12 (sccm) | 100 | 100 | 0 | 0 | 0 | 0 | 0 | 0 | 0 | 0 | 0 | 0 |
| 02 (sccm) | 0 | 0 | 35 | 35 | 35 | 40 | 45 | 50 | 55 | 60 | 65 | 70 |
| He (sccm) | 0 | 0 | 280 | 280 | 280 | 280 | 280 | 280 | 280 | 280 | 280 | 280 |
| SF6 (sccm) | 0 | 0 | 0 | 0 | 46 | 46 | 46 | 46 | 46 | 46 | 46 | 46 |
| Step Type | Stable | Time | Stable | Time | Time | Time | Time | Time | Time | Time | Time | Time |
| Time (sec.) | 30 | 10 | 20 | 7 | 5 | 5 | 5 | 5 | 5 | 5 | 5 | 5 |

1. A method for forming a trench in a device layer of an integrated circuit formed on a semiconductor substrate comprising the steps of:
covering the device layer with an etch resistant trench masking layer to form a plurality of trench regions;
removing semiconductor material from the exposed trench regions by applying an etching fluid that selectively etches the semiconductor substrate with respect to the trench masking layer;
increasing an amount of oxygen during the removing operation to passivate the silicon sidewalls of the trench.

2. The method of claim 1 wherein the etching fluid is SF6.

3. The method of claim 1 wherein the oxygen is increased in discrete steps during equal time intervals.

4. The method of claim 1 wherein the etch resistant pattern defines trenches spaced apart by 1.5 microns or more.

5. The method of claim 1 wherein the etching fluid etches the semiconductor material isotropically with a plasma and the oxygen passivates the etched sidewalls of the trench. isotropically etching an upper portion of the trench.

6. The method of claim 1 wherein the etch resistant masking layer is a low temperature oxide layer.

7. The method of claim 1 wherein the trench surrounds an island including one or more semiconductor devices.

8. The method of claim 1 comprising the further steps of coating the trench with a gate insulating layer and depositing conductive material over the gate insulating layer to form a gate in said trench.

9. The method of claim 8 further comprising the step of forming a source region at the surface adjacent the trench, a channel region adjacent the trench an below the source region, a buried highly doped layer beneath the trench, and conductive via from the buried layer to the surface of the integrated circuit.
